(19) United States
(12) Patent Application Publication
(10) Pub. No.: US 2020/0066978 A1
(43) Pub. Date: Feb. 27, 2020

(54) VARIABLE RESISTANCE MEMORY DEVICE

(71) Applicant: SAMSUNG ELECTRONICS CO., LTD., Suwon-si (KR)

(72) Inventors: Pyojin JEON, Yongin-si (KR); Jaeho JUNG, Seoul (KR); Gwang-Hyun BAEK, Seoul (KR)

(21) Appl. No.: 16/423,557

(22) Filed: May 28, 2019

(30) Foreign Application Priority Data
Aug. 24, 2018 (KR) 10-2018-0099186

(51) Int. Cl. H01L 45/00

(52) U.S. Cl. CPC H01L 45/06; H01L 45/1253

(57) ABSTRACT

A variable resistance memory device includes an interlayer insulating structure on a substrate, the interlayer insulating structure having a hole, a bottom electrode in a lower portion of the hole, and a pattern in an upper portion of the hole, the pattern including at least one of a phase change pattern or an intermediate electrode, a sidewall of the pattern defining an angle with a top surface of the substrate, and the angle decreasing as a vertical distance from the substrate increases.

### CROSS-REFERENCE TO RELATED APPLICATION

Korean Patent Application No. 10-2018-0099186, filed on Aug. 24, 2018, in the Korean Intellectual Property Office, and entitled: “Variable Resistance Memory Device,” is incorporated by reference herein in its entirety.

### BACKGROUND

### 1. Field

Embodiments relate to a variable resistance memory device and, more particularly, to a variable resistance memory device with improved reliability.

### 2. Description of the Related Art

Semiconductor devices have been highly integrated to provide excellent performance and low manufacture costs. The integration density of semiconductor devices directly affects the costs of the semiconductor devices, thereby resulting in a demand of highly integrated semiconductor devices. The integration density of typical two-dimensional (2D) or planar semiconductor devices may be mainly determined by an area which a unit memory cell occupies. Therefore, the integration density of the typical 2D or planar semiconductor devices may be greatly affected by a technique of forming fine patterns. However, since extremely high-priced apparatuses are needed to form fine patterns, the integration density of 2D semiconductor devices continues to increase but is still limited. Three-dimensional (3D) semiconductor devices including three-dimensionally arranged memory cells have been developed to overcome these limitations. In addition, next-generation semiconductor memory devices, e.g., magnetic random access memory (MRAM) devices and phase-change random access memory (PRAM) devices, have been developed to provide high-performance and low power consuming semiconductor memory devices.

### SUMMARY

In an aspect, a variable resistance memory device may include an interlayer insulating structure having a hole on a substrate, a bottom electrode disposed in a lower portion of the hole, and a pattern disposed in an upper portion of the hole. The pattern may include at least one of a phase change pattern or an intermediate electrode. A sidewall of the pattern may form an angle with a top surface of the substrate, and the angle may decrease as a vertical distance from the substrate increases.

In an aspect, a variable resistance memory device may include an interlayer insulating structure having a hole on a substrate, a bottom electrode disposed in a lower portion of the hole, and a pattern disposed in an upper portion of the hole. The pattern may include at least one of a phase change pattern or an intermediate electrode, and a sidewall of the pattern may be concave.

In an aspect, a variable resistance memory device may include an interlayer insulating structure having a hole on a substrate, a bottom electrode disposed in a lower portion of the hole, and a phase change pattern disposed in an upper portion of the hole. A first gradient of a sidewall of the lower portion of the hole may be greater than a second gradient of a sidewall of the upper portion of the hole.

### BRIEF DESCRIPTION OF THE DRAWINGS

Features will become apparent to those of skill in the art by describing in detail exemplary embodiments with reference to the attached drawings, in which:

FIG. 1 illustrates a plan view of a variable resistance memory device according to some embodiments.

FIG. 2 illustrates a cross-sectional view along line I-I′ of FIG. 1, according to embodiments.

FIG. 3A illustrates an enlarged view of portion ‘A’ of FIG. 2, according to embodiments.

FIG. 3B illustrates an enlarged view of portion ‘A’ of FIG. 2, according to other embodiments.

FIG. 4 illustrates an enlarged view of portion ‘A’ of FIG. 2, according to other embodiments.

FIG. 5 illustrates a cross-sectional view along line I-I′ of FIG. 1, according to other embodiments.

FIG. 6 illustrates an enlarged view of portion ‘B’ of FIG. 5.

FIGS. 7, 9, and 14 illustrate plan views of stages in a method of manufacturing a variable resistance memory device according to some embodiments.

FIGS. 8, 10, 11, 12, and 15 illustrate cross-sectional views along lines I-I′ of FIGS. 7, 9, and 14 to illustrate stages in a method of manufacturing a variable resistance memory device.

FIG. 13 illustrates an enlarged view of portion ‘C’ of FIG. 12.

### DETAILED DESCRIPTION

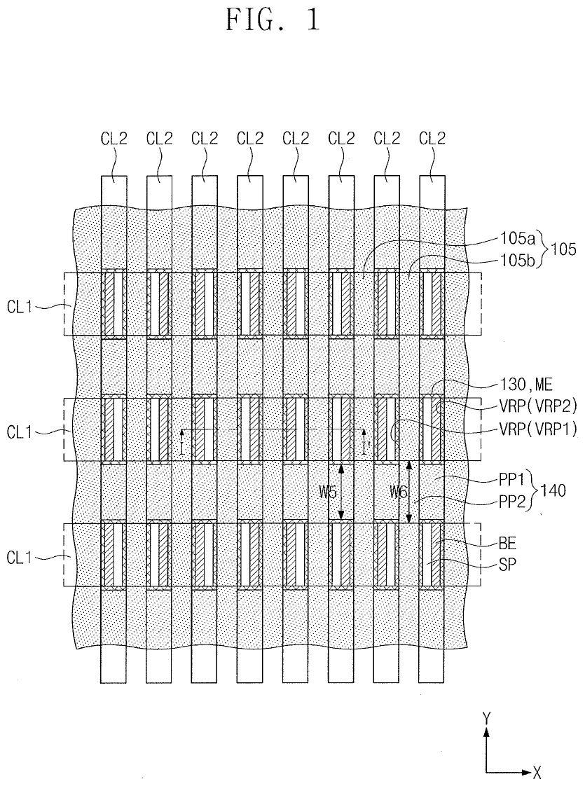

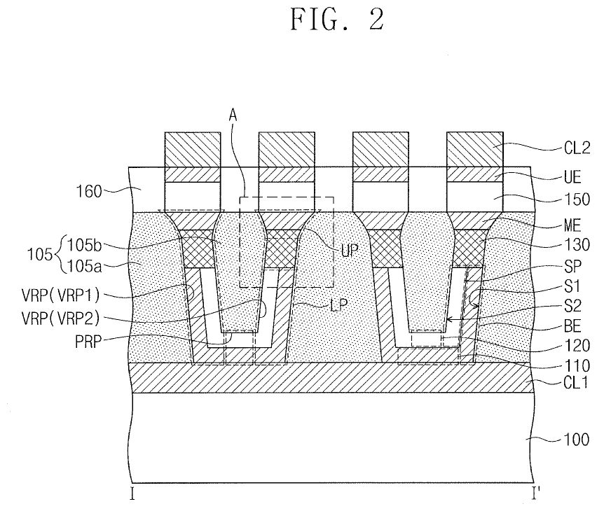

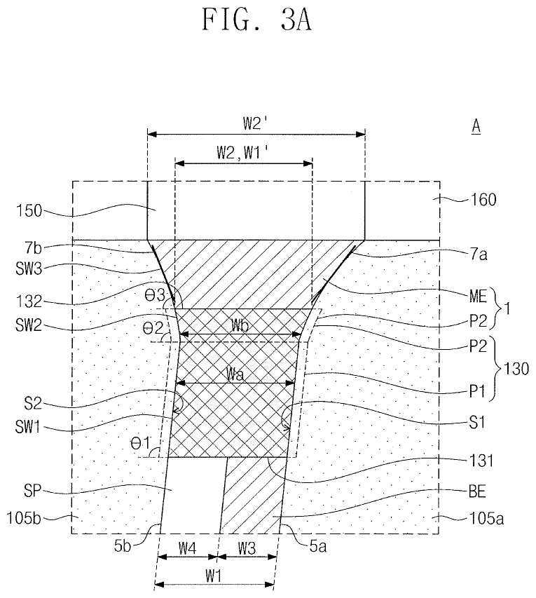

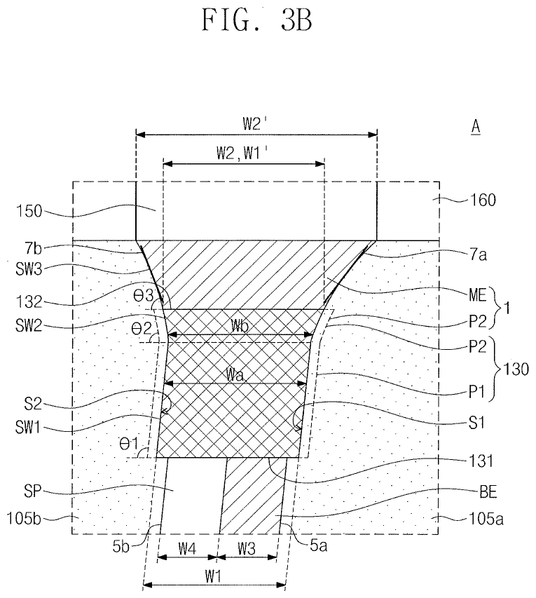

FIG. 1 is a plan view illustrating a variable resistance memory device according to some embodiments. FIG. 2 is a cross-sectional view taken along line I-I′ of FIG. 1 according to some embodiments. FIG. 3A is an enlarged view of portion ‘A’ of FIG. 2. FIG. 3B is an enlarged view of portion ‘A’ of FIG. 2.

Referring to FIGS. 1 and 2, first conductive lines CL1 may be disposed, e.g., directly, on a top surface of a substrate 100. The first conductive lines CL1 may extend in a first direction X and may be spaced apart from each other in a second direction Y intersecting the first direction X. The substrate 100 may include a single-crystalline semiconductor material. For example, the substrate 100 may be a silicon substrate, a silicon-on-insulator (SOI) substrate, a germanium substrate, a germanium-on-insulator (GOI) substrate, and/or a silicon-germanium (SiGe) substrate. The first conductive lines CL1 may include a conductive material. For example, the first conductive lines CL1 may include at least one of a metal material (e.g., copper or aluminum) or a conductive metal nitride (e.g., TiN or WN). In some embodiments, the first conductive lines CL1 may be word lines.

Interlayer insulating structures 105 may be disposed on the substrate 100. The interlayer insulating structures 105 may be disposed on the first conductive lines CL1. Each of the interlayer insulating structures 105 may have vertical holes VRP penetrating the interlayer insulating structure 105. The vertical holes VRP may be spaced apart from each other and may be arranged in the first direction X and the second direction Y. The vertical holes VRP may include first vertical holes VRP1 and second vertical holes VRP2, which are arranged in the first direction X on each of the first conductive lines CL1. The first vertical holes VRP1 and the second vertical holes VRP2 may be alternately arranged in the first direction X. The vertical holes VRP may expose top surfaces of the first conductive lines CL1.

Each of the interlayer insulating structures 105 may include horizontal holes PRP. The horizontal holes PRP may expose the top surfaces of the first conductive lines CL1. Each of the horizontal holes PRP may be disposed between a pair of the first vertical hole VRP1 and the second vertical hole VRP2 adjacent to each other in the first direction X and may connect the pair of the first and second vertical holes VRP1 and VRP2. For example, as illustrated in FIGS. 1-2, each of the horizontal holes PRP may extend, e.g., directly, on a respective one of the first conductive lines CL1 through the interlayer insulating structures 105 to be connected between adjacent first and second vertical hole VRP1 and VRP2 in the first direction X. In other words, the pair of first and second vertical holes VRP1 and VRP2 and one horizontal hole PRP therebetween may constitute one hole, e.g., a single continuous hole through the interlayer insulating structure 105.

Each of the interlayer insulating structures 105 may include first interlayer insulating patterns 105a and second interlayer insulating patterns 105b. The first interlayer insulating patterns 105a and the second interlayer insulating patterns 105b may be alternately arranged in the first direction X on the top surface of each of the first conductive lines CL1.

For example, each of the first interlayer insulating patterns 105a may be disposed on the first conductive line CL1 between a pair of the first and second vertical holes VRP1 and VRP2 and another pair of the first and second vertical holes VRP1 and VRP2. Here, the pair of first and second vertical holes VRP1 and VRP2 may be adjacent to each other in the first direction X, and the other pair of first and second vertical holes VRP1 and VRP2 may be adjacent to each other in the first direction X. For example, as illustrated in FIG. 2, each of the first interlayer insulating patterns 105a may be disposed, e.g., directly, on the first conductive line CL1 between connected pairs of first and second vertical holes VRP1 and VRP2. In other words, one first interlayer insulating pattern 105a may separate between first and second vertical holes VRP1 and VRP2 of different pairs, i.e., separate between first and second vertical holes VRP1 and VRP2 that are not connected to each other via a horizontal hole PRP.

For example, each of the second interlayer insulating patterns 105b may be disposed on the first conductive line CL1 between the first vertical hole VRP1 and the second vertical hole VRP2. For example. as illustrated in FIG. 2, each of the second interlayer insulating patterns 105b may be disposed on a top of a respective horizontal hole PRP between first and second vertical holes VRP1 and VRP2 that are connected to each other via the respective horizontal hole PRP. For example, each of the horizontal holes PRP may be disposed between a respective second interlayer insulating pattern 105b and the first conductive line CL1.

A first sidewall S1 of each of the vertical holes VRP may be formed or defined by the first interlayer insulating pattern 105a. A second sidewall S2 of each of the vertical holes VRP, which is opposite to the first sidewall S1, may be formed or defined by the second interlayer insulating pattern 105b. Referring to FIG. 2, the vertical hole VRP may include a lower portion LP and an upper portion UP. A bottom electrode BE, a spacer SP, and a first portion P1 (FIG. 3A) of a phase change pattern 130 may be disposed in the lower portion LP of the vertical hole VRP. A second portion P2 (FIG. 3A) of the phase change pattern 130 and an intermediate electrode ME may be disposed in the upper portion UP of the vertical hole VRP.

In some embodiments, referring to FIGS. 2 and 3A, gradients 5a and 5b of the first and second sidewalls S1 and S2 of the lower portion LP of the vertical hole VRP may be different from gradients 7a and 7b of the first and second sidewalls S1 and S2 of the upper portion UP of the vertical hole VRP. For example, the gradients 5a and 5b of the first and second sidewalls S1 and S2 of the lower portion LP of the vertical hole VRP may be greater than the gradients 7a and 7b of the first and second sidewalls S1 and S2 of the upper portion UP of the vertical hole VRP. For example, the gradients, e.g., inclination angels, of the first and second sidewalls S1 and S2 of the lower portion LP and of the upper portion UP may be measured relatively to the bottom of the substrate 100. The first and second sidewalls S1 and S2 of the lower portion LP of the vertical hole VRP may be substantially flat. A width of the upper portion UP of the vertical hole VRP may increase as a vertical distance from the substrate 100 increases. The first and second sidewalls S1 and S2 of the upper portion UP of the vertical hole VRP may be rounded. The first and second interlayer insulating patterns 105a and 105b may be formed of, e.g., silicon nitride.

The bottom electrodes BE may be disposed in the vertical holes VRP. The bottom electrodes BE may be spaced apart from each other and may be arranged in the first direction X and the second direction Y when viewed in a plan view. Each of the bottom electrodes BE may be disposed on the first sidewall S1 of the lower portion LP of each of the vertical holes VRP, e.g., each bottom electrode BE may be disposed on the first sidewall S1 in each of the first and second vertical holes VRP1 and VRP2. The bottom electrode BE may be in, e.g., direct, contact with the first sidewall S1 of the lower portion LP of the vertical hole VRP and the first conductive line CL1. For example, the bottom electrodes BE may include at least one of W, Ti, Al, Cu, C, CN, TiN, TiAlN, TiSiN, TiCN, WN, CoSiN, WSiN, TaN, TaCN, TaSiN, or TiO.

A horizontal connection pattern 110 may be disposed in each of the horizontal holes PRP. For example, the horizontal connection pattern 110 may be connected to the bottom electrodes BE disposed in the pair of the first and second vertical holes VRP1 and VRP2. In other words, the horizontal connection pattern 110 may connect the bottom electrode BE disposed in the first vertical hole VRP1 to the bottom electrode BE disposed in the second vertical hole VRP2. The horizontal connection pattern 110 may be in contact with the top surface of the first conductive line CL1. The horizontal connection pattern 110 may include the same material as the bottom electrode BE. For example, the horizontal connection pattern 110 may include at least one of W, Ti, Al, Cu, C, CN, TiN, TiAlN, TiSiN, TiCN, WN, CoSiN, WSiN, TaN, TaCN, TaSiN, or TiO.

The spacers SP may be disposed in the vertical holes VRP. The spacers SP may be spaced apart from each other and may be arranged in the first direction X and the second direction Y when viewed in a plan view. Each of the spacers SP may be disposed on the second sidewall S2 of the lower portion LP of each of the vertical holes VRP. The spacer SP may be disposed on one sidewall of the bottom electrode BE, e.g., each spacer SP may be between the second sidewall S2 and a corresponding bottom electrode BE in each of the first and second vertical holes VRP1 and VRP2. The spacer SP may be in contact with the bottom electrode BE and the second sidewall S2 of the lower portion LP of the vertical hole VRP. For example, the spacer SP may include silicon oxide or poly-silicon.

A horizontal spacer 120 may be disposed on a top surface of the horizontal connection pattern 110 in each of the horizontal holes PRP. For example, the horizontal spacer 120 may be connected to the spacers SP disposed in the pair of first and second vertical holes VRP1 and VRP2. In other words, the horizontal spacer 120 may connect the spacer SP disposed in the first vertical hole VRP1 to the spacer SP disposed in the second vertical hole VRP2. The horizontal spacer 120 may be in contact with the horizontal connection pattern 110 and the second interlayer insulating pattern 105b. The horizontal spacer 120 may include the same material as the spacer SP. For example, the horizontal spacer 120 may include silicon oxide or poly-silicon. For example, as illustrated in FIG. 2, a combined shape of the horizontal spacer 120 between the spacers SP in a single vertical hole VRP may trace, e.g., have a same shape, as a combined shape of the horizontal connection pattern 110 between the bottom electrodes BE in the same vertical hole VRP, e.g., topmost surfaces of the spacers SP and the bottom electrodes BE may be level with each other.

The phase change pattern 130 may be disposed on the topmost surfaces of the bottom electrode BE and the spacer SP in each of the vertical holes VRP. The phase change patterns 130 may be spaced apart from each other and may be arranged in the first direction X and the second direction Y. Each of the phase change patterns 130 may be disposed in the lower portion LP and the upper portion UP of each of the vertical holes VRP. Each of the phase change patterns 130 may be in contact with the first and second sidewalls S1 and S2 of the lower and upper portions LP and UP of each of the vertical holes VRP. The phase change patterns 130 may include at least one material having properties capable of storing data or information. In some embodiments, the phase change patterns 130 may include a material of which a phase is reversibly changeable between a crystalline state and an amorphous state by temperature. For example, the phase change patterns 130 may be formed of a compound that includes at least one of Te or Se (i.e., chalcogenide elements) and at least one of Ge, Sb, Bi, Pb, Sn, Ag, As, S, Si, In, Ti, Ga, P, O, or C. For example, the phase change patterns 130 may include at least one of GeSbTe, GeTeAs, SbTeSe, GeTe, SbTe, SeTeSn, GeTeSe, SbSeBi, GeBiTe, GeTeTi, InSe, GaTeSe, or InSbTe.

In other embodiments, the phase change patterns 130 may include at least one of a perovskite compound or a conductive metal oxide. For example, the phase change patterns 130 may include at least one of niobium oxide, titanium oxide, nickel oxide, zirconium oxide, vanadium oxide, (Pr,Ca)MnO₃ (PCMO), strontium-titanium oxide, barium-strontium-titanium oxide, strontium-zirconium oxide, barium-zirconium oxide, or barium-strontium-zirconium oxide. When the phase change patterns 130 include a transition metal oxide, a dielectric constant of the phase change patterns 130 may be greater than a dielectric constant of silicon oxide. In still other embodiments, the phase change patterns 130 may have a double-layer structure of a conductive metal oxide layer and a tunnel insulating layer or may have a triple-layer structure of a first conductive metal oxide layer, a tunnel insulating layer and a second conductive metal oxide layer. The tunnel insulating layer may include aluminum oxide, hafnium oxide, or silicon oxide.

Referring to FIG. 3A, a first width W1 of a bottom surface 131 of the phase change pattern 130 may be less than a second width W2 of a top surface 132 of the phase change pattern 130 (W1<W2). In some embodiments, a sum of a third width W3 of the bottom electrode BE and a fourth width W4 of the spacer SP may be substantially equal to the first width W1 of the bottom surface 131 of the phase change pattern 130 (W3+W4=W1). In other embodiments, a sum of the third width W3 of the bottom electrode BE and the fourth width W4 of the spacer SP may be less than the first width W1 of the bottom surface 131 of the phase change pattern 130 (W3+W4<W1), as illustrated in FIG. 3B. A sidewall of the phase change pattern 130 may be a concave surface. The top surface 132 of the phase change pattern 130 may be located at a lower level than a top surface of the interlayer insulating structure 105. The phase change pattern 130 may include the first portion P1 and the second portion P2. The first portion P1 may be disposed between the bottom electrode BE and the intermediate electrode ME disposed on the top surface 132 of the phase change pattern 130 and between the spacer SP and the intermediate electrode ME. The second portion P2 may be disposed between the first portion P1 and the intermediate electrode ME. The first portion P1 of the phase change pattern 130 may be disposed in the lower portion LP of the vertical hole VRP, and the second portion P2 of the phase change pattern 130 may be disposed in the upper portion UP of the vertical hole VRP. A width Wa of the first portion P1 may be substantially uniform. A width Wb of the second portion P2 may become progressively greater from the first portion P1 toward the intermediate electrode ME. In some embodiments, the first portion P1 may have a rhombic or rectangular shape in a cross-sectional view, and the second portion P2 may have a tapered shape in a cross-sectional view. A sidewall SW1 of the first portion P1 may form a first angle θ1 with a top surface of the substrate 100, and a sidewall SW2 of the second portion P2 may form a second angle θ2 with the top surface of the substrate 100. Here, the second angle θ2 may be different from the first angle θ1. For example, the first angle θ1 may be greater than the second angle θ2 (θ1>θ2).

The intermediate electrode ME may be disposed on the top surface 132 of the phase change pattern 130 in each of the vertical holes VRP. The intermediate electrode ME may be disposed in the upper portion UP of the vertical hole VRP. The intermediate electrode ME may be in contact with the first and second sidewalls S1 and S2 of the upper portion UP of the vertical hole VRP. A top surface of the intermediate electrode ME may be substantially coplanar with the top surface of the interlayer insulating structure 105. For example, the intermediate electrode ME may include at least one of W, Ti, Al, Cu, C, CN, TiN, TiAlN, TiSiN, TiCN, WN, CoSiN, WSiN, TaN, TaCN, TaSiN, or TiO.

Referring to FIGS. 3A and 3B, a first width W1′ of a bottom surface of the intermediate electrode ME may be different from a second width W2′ of the top surface of the intermediate electrode ME. The first width W1′ may be less than the second width W2′ (W1′<W2′). The first width W1′ of the bottom surface of the intermediate electrode ME may be substantially equal to the second width W2 of the top surface 132 of the phase change pattern 130 (W1′=W2). The sum of the third width W3 of the bottom electrode BE and the fourth width W4 of the spacer SP may be less than the first width W1′ of the bottom surface of the intermediate electrode ME (W3+W4<W1′). A width of the intermediate electrode ME may become greater from its bottom surface toward its top surface. A third angle θ3 of a sidewall SW3 of the intermediate electrode ME with respect to the top surface of the substrate 100 may be equal to or less than the second angle θ2 of the sidewall SW2 of the second portion P2 of the phase change pattern 130 (θ3<θ2). The intermediate electrode ME may have a tapered shape when viewed in a cross-sectional view. In some embodiments, a pattern 1 filling the upper portion UP of each of the vertical holes VRP may be defined. In detail, the pattern 1 may be disposed in the upper portion UP of each of the vertical holes VRP and may include the second portion P2 of the phase change pattern 130 and the intermediate electrode ME. A sidewall of the pattern 1 may form an angle with the top surface of the substrate 100, and the angle may decrease as a vertical distance from the substrate 100 increases. For example, the second angle θ2 of the sidewall SW2 of the second portion P2 of the phase change pattern 130 may decrease as a vertical distance from the substrate 100 increases, and the third angle θ3 of the sidewall SW3 of the intermediate electrode ME may decrease as a vertical distance from the substrate 100 increases.

Referring back to FIG. 1, each of third interlayer insulating patterns 140 may be disposed on the top surface of the substrate 100 between the first conductive lines CL1 adjacent to each other in the second direction Y. The third interlayer insulating patterns 140 may extend, e.g., continuously, in the first direction X. The third interlayer insulating patterns 140 may be in contact with sidewalls of the first interlayer insulating patterns 105a and sidewalls of the second interlayer insulating patterns 105b. Each of the third interlayer insulating patterns 140 may include a first portion PP1 disposed between the intermediate electrodes ME adjacent to each other in the second direction Y and a second portion PP2 disposed between the second interlayer insulating patterns 105b adjacent to each other in the second direction Y. A fifth width W5 of the first portion PP1 in the second direction Y may be less than a sixth width W6 of the second portion PP2 in the second direction Y (W5<W6). Top surfaces of the third interlayer insulating patterns 140 may be substantially coplanar with the top surfaces of the intermediate electrodes ME and the top surfaces of the interlayer insulating structures 105. For example, the third interlayer insulating patterns 140 may include silicon nitride.

As illustrated in FIG. 2, switching patterns 150 may be disposed on the top surfaces of the intermediate electrodes ME. The switching patterns 150 may be spaced apart from each other and may be arranged in the first direction X and the second direction Y. Each of the switching patterns 150 may be a diode or may be an element based on a threshold switching phenomenon having a nonlinear I-V curve (e.g., a S-shaped I-V curve). For example, each of the switching patterns 150 may be an ovonic threshold switch (OTS) element having a bi-directional characteristic. In some embodiments, the switching pattern 150 may be the diode. In this case, the switching pattern 150 may include a first junction pattern and a second junction pattern. The first junction pattern may have a first conductivity type, and the second junction pattern may have a second conductivity type different from the first conductivity type. For example, the first conductivity type may be an N type, and the second conductivity type may be a P type. For example, the second junction pattern may include dopants of the second conductivity type. The first junction pattern may include dopants of the first conductivity type and dopants of the second conductivity type. In this case, a concentration of the first conductivity type dopants may be higher than a concentration of the second conductivity type dopants, in the first junction pattern. In some embodiments, the switching pattern 150 may be a silicon diode or oxide diode which has a rectifying property. For example, the switching pattern 150 may be a silicon diode of P-type silicon and N-type silicon or may be an oxide diode of P-type NiOₓ and N-type TiOₓ or an oxide diode of P-type CuOₓ and N-type TiOₓ.

Top electrodes UE may be disposed on top surfaces of the switching patterns 150. The top electrodes UE may be connected to the switching patterns 150. For example, the top electrodes UE may include at least one of W, Ti, Al, Cu, C, CN, TiN, TiAlN, TiSiN, TiCN, WN, CoSiN, WSiN, TaN, TaCN, TaSiN, or TiO. A fourth interlayer insulating layer 160 may be disposed on the top surfaces of the interlayer insulating structures 105 and the top surfaces of the third interlayer insulating patterns 140. The fourth interlayer insulating layer 160 may cover sidewalls of the switching patterns 150 and sidewalls of the top electrodes UE. A top surface of the fourth interlayer insulating layer 160 may be substantially coplanar with top surfaces of the top electrodes UE. For example, the fourth interlayer insulating layer 160 may include a silicon nitride layer.

Second conductive lines CL2 may be disposed on the top surfaces of the top electrodes UE. Each of the second conductive lines CL2 may extend in the second direction Y along the top electrodes UE arranged in the second direction Y. The second conductive lines CL2 may be spaced apart from each other and may be arranged in the first direction X. Each of the second conductive lines CL2 may be electrically connected to the phase change patterns 130 arranged in the second direction Y. In some embodiments, the second conductive lines CL2 may be bit lines. For example, the second conductive lines CL2 may include at least one of a metal material (e.g., copper or aluminum) or a conductive metal nitride (e.g., TiN or WN).

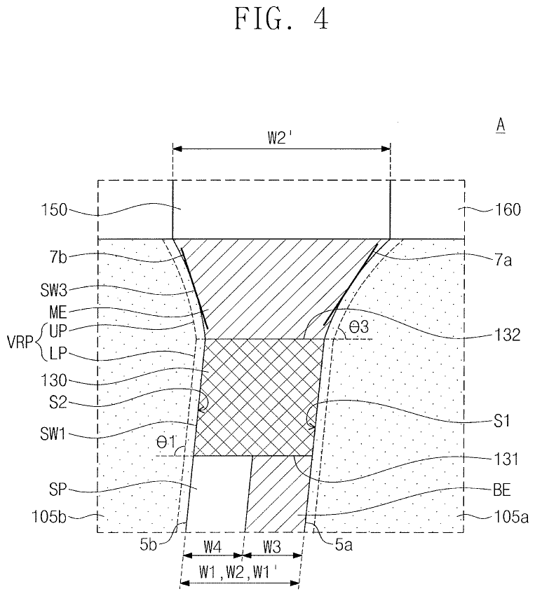

FIG. 4 is an enlarged view of the portion ‘A’ of FIG. 2 according to another embodiment. Hereinafter, the same elements or components as described in the above embodiments will be indicated by the same reference numerals or the same reference designators, and the descriptions thereto will be omitted or mentioned only briefly for the purpose of ease and convenience in explanation.

Referring to FIG. 4, the phase change pattern 130 may be disposed in the lower portion LP of each of the vertical holes VRP. The intermediate electrode ME may be disposed in the upper portion UP of the vertical hole VRP. In some embodiments, the intermediate electrode ME may correspond to the pattern 1 illustrated in FIGS. 3A and 3B. The phase change pattern 130 may be in contact with the first and second sidewalls S1 and S2 of the lower portion LP of the vertical hole VRP. Sidewalls SW1 of the phase change pattern 130 may be substantially flat. The intermediate electrode ME may be in contact with the first and second sidewalls S1 and S2 of the upper portion UP of the vertical hole VRP. In some embodiments the a first width W1 of the bottom surface 131 of the phase change pattern 130 may be substantially equal to the second width W2 of the top surface 132 of the phase change pattern 130 (W1=W2). In other embodiments, even though not shown in the drawings, the first width W1 of the bottom surface 131 of the phase change pattern 130 may be less than the second width W2 of the top surface 132 of the phase change pattern 130 (W1<W2). The second width W2 of the top surface 132 of the phase change pattern 130 may be substantially equal to the first width W1′ of a bottom surface of the intermediate electrode ME (W2=W1′). In some embodiments, the phase change pattern 130 may have a rhombic or rectangular shape when viewed in a cross-sectional view, and the intermediate electrode ME may have a tapered shape when viewed in a cross-sectional view. The sidewall SW1 of the phase change pattern 130 may form the first angle θ1 with the top surface of the substrate 100, and the sidewall SW3 of the intermediate electrode ME may form the third angle θ3 with the top surface of the substrate 100. Here, the third angle θ3 may be different from the first angle θ1. For example, the first angle θ1 may be greater than the third angle θ3 (θ1>θ3). In some embodiments, the third angle θ3 may decrease as a vertical distance from the substrate 100 increases. The sidewall SW3 of the intermediate electrode ME may be a concave surface.

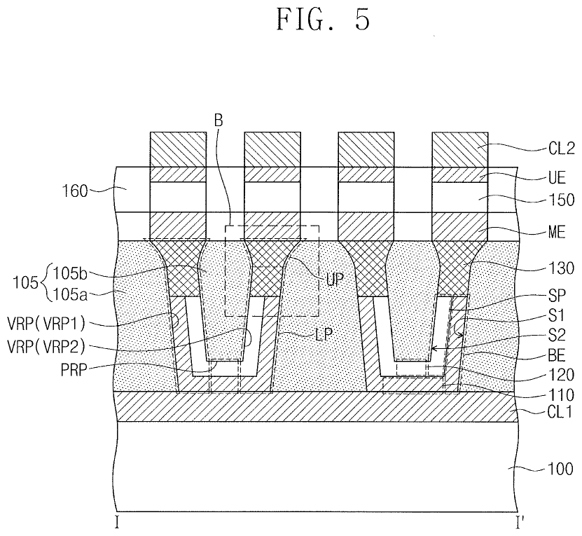

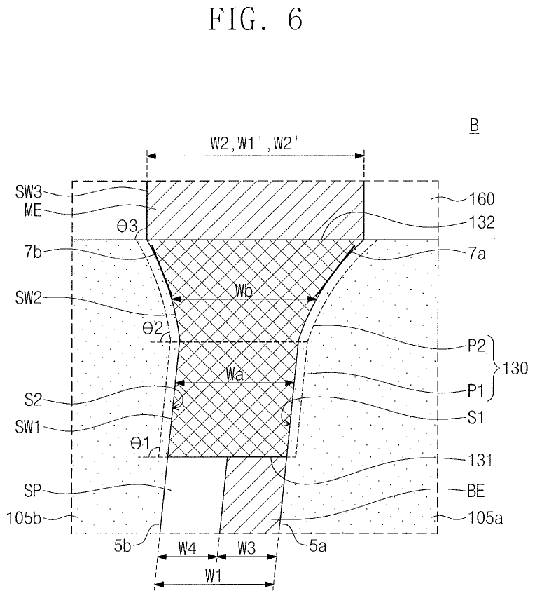

FIG. 5 is a cross-sectional view taken along line I-I′ of FIG. 1 to illustrate a variable resistance memory device according to some embodiments. FIG. 6 is an enlarged view of a portion ‘B’ of FIG. 5. Hereinafter, the same elements or components as described in the above embodiments will be indicated by the same reference numerals or the same reference designators, and the descriptions thereto will be omitted or mentioned only briefly for the purpose of ease and convenience in explanation.

Referring to FIGS. 5 and 6, the phase change pattern 130 may be disposed in each of the vertical holes VRP. The phase change pattern 130 may be in contact with the first and second sidewalls S1 and S2 of the lower portion LP of the vertical hole VRP and the first and second sidewalls S1 and S2 of the upper portion UP of the vertical hole VRP. The top surface 132 of the phase change pattern 130 may be substantially coplanar with the top surface of the interlayer insulating structure 105. The first width W1 of the bottom surface 131 of the phase change pattern 130 may be less than the second width W2 of the top surface 132 of the phase change pattern 130 (W1<W2).

The phase change pattern 130 may include the first portion P1 disposed between the bottom electrode BE and the intermediate electrode ME and between the spacer SP and the intermediate electrode ME, and the second portion P2 disposed between the first portion P1 and the intermediate electrode ME. The first portion P1 may be disposed in the lower portion LP of the vertical hole VRP, and the second portion P2 may be disposed in the upper portion UP of the vertical hole VRP. In some embodiments, the second portion P2 of the phase change pattern 130 may correspond to the pattern 1 illustrated in FIGS. 3A and 3B. The width Wa of the first portion P1 may be substantially uniform, and the width Wb of the second portion P2 may become greater from the first portion P1 toward the intermediate electrode ME. In some embodiments, the first portion P1 may have a rhombic or rectangular shape in a cross-sectional view, and the second portion P2 may have a tapered shape in a cross-sectional view. The sidewall SW1 of the first portion P1 may form the first angle θ1 with the top surface of the substrate 100, and the sidewall SW2 of the second portion P2 may form the second angle θ2 with the top surface of the substrate 100. Here, the second angle θ2 may be different from the first angle θ1. For example, the first angle θ1 may be greater than the second angle θ2 (01>02). In some embodiments, the second angle θ2 of the sidewall SW2 of the second portion P2 of the phase change pattern 130 may decrease as a vertical distance from the substrate 100 increases. In some embodiments, the sidewall SW1 of the first portion P1 may be substantially flat, and the sidewall SW2 of the second portion P2 may be a concave surface.

The intermediate electrode ME may be disposed on the top surface 132 of the phase change pattern 130. A top surface of the intermediate electrode ME may be located at a higher level than the top surface of the interlayer insulating structure 105. A sidewall SW3 of the intermediate electrode ME may be covered by the fourth interlayer insulating layer 160. The intermediate electrode ME may be spaced apart from the first and second sidewalls S1 and S2 of the upper portion UP of the vertical hole VRP. The sidewall SW3 of the intermediate electrode ME may form a substantially right angle with the top surface of the substrate 100 (θ3=90°). The first width W1′ of the bottom surface of the intermediate electrode ME may be substantially equal to the second width W2′ of the top surface of the intermediate electrode ME (W1′=W2′). The second width W2 of the top surface 132 of the phase change pattern 130 may be substantially equal to the first width W1′ and the second width W2′ of the intermediate electrode ME (W2=W1′=W2′). The sum of the third width W3 of the bottom electrode BE and the fourth width W4 of the spacer SP may be less than each of the first width W1′ and the second width W2′ of the intermediate electrode ME (W3+W4<W1′=W2′).

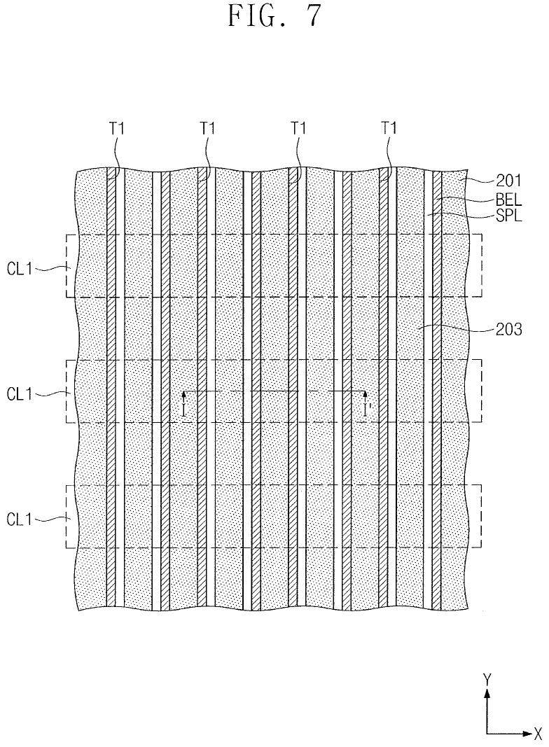

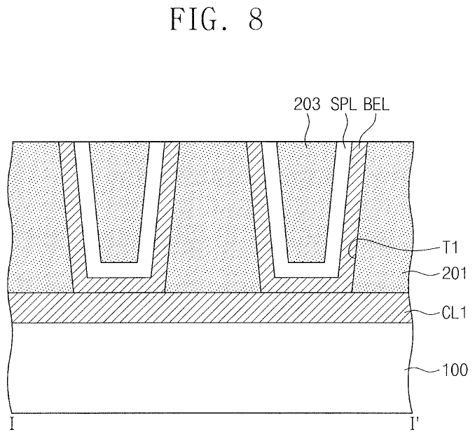

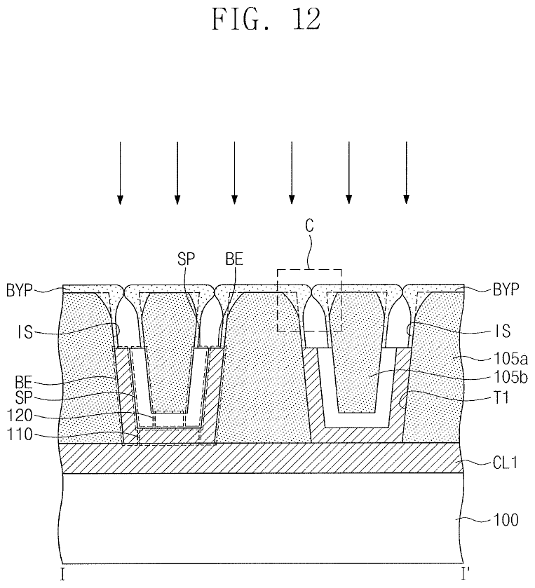

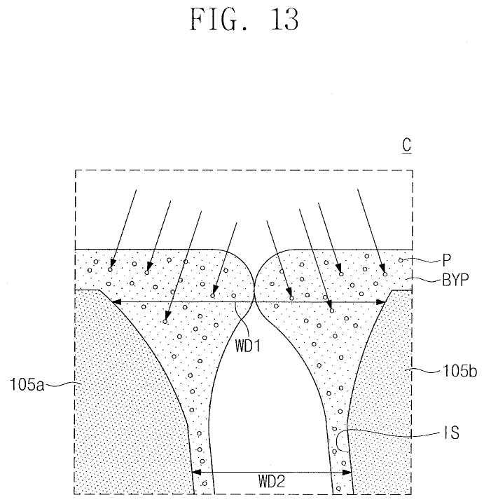

FIGS. 7, 9, and 14 are plan views illustrating stages in a method of manufacturing a variable resistance memory device, according to some embodiments. FIGS. 8, 10, 11, 12, and 15 are cross-sectional views taken along lines I-I′ of FIGS. 7, 9 and 14. FIG. 13 is an enlarged view of portion ‘C’ of FIG. 12.

Referring to FIGS. 7 and 8, the first conductive lines CL1 may be formed on the substrate 100. The substrate 100 may include a single-crystalline semiconductor material. For example, the substrate 100 may be a silicon substrate, a silicon-on-insulator (SOI) substrate, a germanium substrate, a germanium-on-insulator (GOI) substrate, and/or a silicon-germanium (SiGe) substrate. In some embodiments, a conductive layer may be formed on the substrate 100, and the first conductive lines CL1 may be formed by patterning the conductive layer. In certain embodiments, an insulating layer having trenches may be formed on the substrate 100, and the first conductive lines CL1 may be formed in the trenches by filling the trenches with a conductive material. The first conductive lines CL1 may extend in the first direction X and may be spaced apart from each other in the second direction Y intersecting the first direction X. For example, the first conductive lines CL1 may include at least one of a metal material (e.g., copper or aluminum) or a conductive metal nitride (e.g., TiN or WN).

A first interlayer insulating layer 201 may be formed on the substrate 100 to cover the first conductive lines CL1, and first trenches T1 may be formed in the first interlayer insulating layer 201. The first trenches T1 may be formed by patterning the first interlayer insulating layer 201 and may expose portions of top surfaces of the first conductive lines CL1. The first trenches T1 may extend in the second direction Y to intersect the first conductive lines CL1 and may be spaced apart from each other in the first direction X. A width of each of the first trenches T1 may become progressively greater from its bottom end toward its top end. In other words, sidewalls of the first trenches T1 may be inclined with respect to the top surface of the substrate 100. Alternatively, the sidewalls of the first trenches T1 may be substantially perpendicular to the top surface of the substrate 100. For example, the first interlayer insulating layer 201 may include a silicon nitride layer.

Bottom electrode layers BEL may be formed in the first trenches T1, respectively. In some embodiments, a metal layer may be formed to conformally cover bottom surfaces and sidewalls of the first trenches T1 and a top surface of the first interlayer insulating layer 201, and a planarization process may be performed on the metal layer until the top surface of the first interlayer insulating layer 201 is exposed, thereby forming the bottom electrode layers BEL. The bottom electrode layers BEL may conformally cover the bottom surfaces and the sidewalls of the first trenches T1. The bottom electrode layers BEL may be in contact with the first conductive lines CL1. For example, the bottom electrode layers BEL may include at least one of W, Ti, Al, Cu, C, CN, TiN, TiAlN, TiSiN, TiCN, WN, CoSiN, WSiN, TaN, TaCN, TaSiN, or TiO.

Spacer layers SPL may be formed on the bottom electrode layers BEL, respectively. In some embodiments, a silicon layer (or a silicon oxide layer) may be formed to conformally cover the bottom electrode layers BEL formed in the first trenches TI and the first interlayer insulating layer 201, and a planarization process may be performed on the silicon layer (or the silicon oxide layer) until the top surface of the first interlayer insulating layer 201 is exposed, thereby forming the spacer layers SPL. The spacer layers SPL may conformally cover the bottom electrode layers BEL, respectively. For example, the spacer layers SPL may include silicon oxide or poly-silicon.

Second interlayer insulating layers 203 may be formed in the first trenches T1, respectively. In some embodiments, an insulating layer filling the first trenches T1 and covering the spacer layers SPL and the first interlayer insulating layer 201 may be formed, and a planarization process may be performed on the insulating layer until the top surface of the first interlayer insulating layer 201 is exposed, thereby forming the second interlayer insulating layers 203. For example, the second interlayer insulating layers 203 may include silicon nitride. In certain embodiments, the metal layer, the silicon layer (or the silicon oxide layer) and the insulating layer may be sequentially formed on the substrate 100 having the first trenches T1, and a planarization process may be performed on the insulating layer, the silicon layer (or the silicon oxide layer) and the metal layer until the first interlayer insulating layer 201 is exposed, thereby forming the bottom electrode layers BEL, the spacer layers SPL, and the second interlayer insulating layers 203 in the first trenches T1.

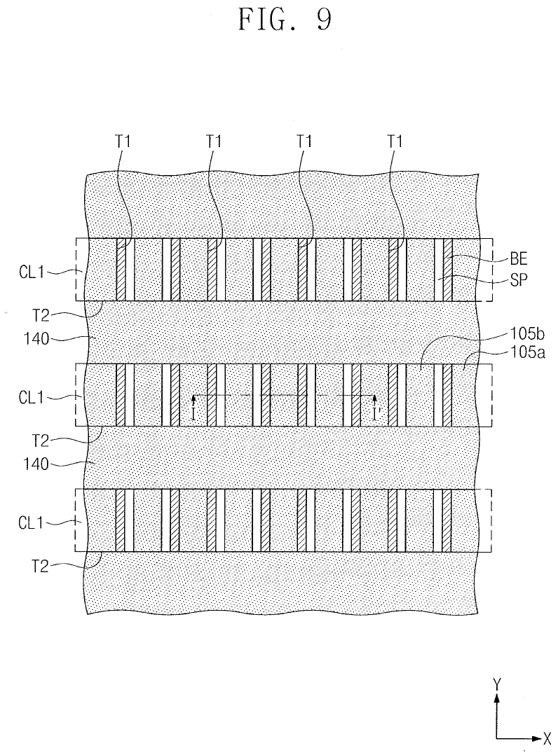

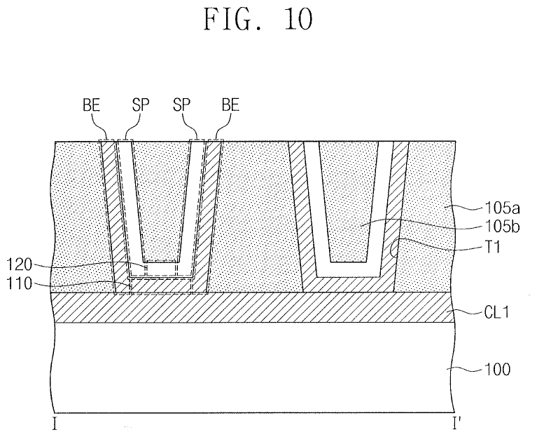

Referring to FIGS. 9 and 10, second trenches T2 may be formed by patterning the second interlayer insulating layers 203, the bottom electrode layers BEL, the spacer layers SPL, and the first interlayer insulating layer 201. The patterning process may etch portions of the second interlayer insulating layers 203, portions of the bottom electrode layers BEL, portions of the spacer layers SPL, and portions of the first interlayer insulating layer 201, which do not overlap with the first conductive lines CL1 when viewed in a plan view. The second trenches T2 may extend in the first direction X and may be spaced apart from each other in the second direction Y, e.g., the second trenches T2 and the first conductive lines CL1 may be parallel to each other and alternate along the second direction Y. Since the second trenches T2 are formed, the first trenches T1 may be locally disposed. e.g., only, on the first conductive lines CL1. The first trenches T1 may be spaced apart from each other in the first direction X and the second direction Y.

The first interlayer insulating patterns 105a may be formed by patterning the first interlayer insulating layer 201. The first interlayer insulating patterns 105a may overlap with the first conductive lines CL1, and each of the first interlayer insulating patterns 105a may be disposed between the first trenches T1 adjacent to each other in the first direction X. The first interlayer insulating patterns 105a may be in contact with top surfaces of the first conductive lines CL1. The second interlayer insulating patterns 105b may be formed by patterning the second interlayer insulating layers 203. The second interlayer insulating patterns 105b may be formed in the first trenches T1. In some embodiments, the first interlayer insulating patterns 105a and the second interlayer insulating patterns 105b may be alternately arranged in the first direction X on each of the first conductive lines CL1.

The pair of bottom electrodes BE and the horizontal connection pattern 110 may be formed by the patterning of the bottom electrode layer BEL. The pair of bottom electrodes BE and the horizontal connection pattern 110 may be formed in each of the first trenches T1. One of the pair of bottom electrodes BE may be disposed on one sidewall of the first trench T1, which is parallel to the second direction Y. The other of the pair of bottom electrodes BE may be disposed on another sidewall of the first trench T1, which is opposite to the one sidewall of the first trench T1. The horizontal connection pattern 110 may be formed on the bottom surface of the first trench T1. The horizontal connection pattern 110 may connect the pair of bottom electrodes BE formed in each of the first trenches T1. For example, as illustrated in FIG. 10, the pair of bottom electrodes BE and the horizontal connection pattern 110 may be integral with each other, i.e., a single and seamless structure.

The pair of spacers SP and the horizontal spacer 120 may be formed by the patterning of the spacer layer SPL. The pair of spacers SP and the horizontal spacer 120 may be formed in each of the first trenches T1. One of the pair of spacers SP may be disposed on a sidewall of one of the pair of bottom electrodes BE, and the other of the pair of spacers SP may be disposed on a sidewall of the other of the pair of bottom electrodes BE. The horizontal spacer 120 may be formed on a top surface of the horizontal connection pattern 110. The horizontal spacer 120 may connect the pair of spacers SP formed in each of the first trenches T1. For example, as illustrated in FIG. 10, the pair of spacers SP and the horizontal spacer 120 may be integral with each other, i.e., a single and seamless structure.

The third interlayer insulating patterns 140 may be formed in the second trenches T2. In some embodiments, an insulating layer may be formed to fill the second trenches T2 and to cover top surfaces of the spacers SP, top surfaces of the bottom electrodes BE, top surfaces of the first interlayer insulating patterns 105a, and top surfaces of the second interlayer insulating patterns 105b. Then, a planarization process may be performed on the insulating layer to locally form the third interlayer insulating patterns 140 in the second trenches T2, respectively. The third interlayer insulating patterns 140 may extend in the first direction X and may be spaced apart from each other in the second direction Y. Top surfaces of the third interlayer insulating patterns 140 may be substantially coplanar with the top surfaces of the first and second interlayer insulating patterns 105a and 105b. For example, the third interlayer insulating patterns 140 may include silicon nitride.

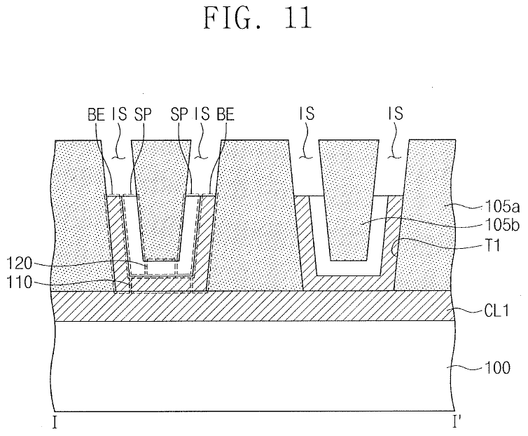

Referring to FIG. 11, upper portions of the bottom electrodes BE and upper portions of the spacers SP may be etched, e.g., a first etching process. Thus, top surfaces of the bottom electrodes BE and top surfaces of the spacers SP may be recessed from the top surfaces of the first to third interlayer insulating patterns 105a, 105b, and 140. Inner spaces IS surrounded by the first to third interlayer insulating patterns 105a, 105b, and 140 may be formed on the top surfaces of the bottom electrodes BE and the top surfaces of the spacers SP.

Referring to FIGS. 12 and 13, an etching process, i.e., a second etching process different from the first etching process, may be performed on the first to third interlayer insulating patterns 105a, 105b, and 140. The etching process may etch the top surfaces of the first to third interlayer insulating patterns 105a, 105b and 140, and sidewalls of the inner spaces IS. While the first to third interlayer insulating patterns 105a, 105b, and 140 are etched by an etchant (e.g., an etching gas or an etching solution) used in the etching process, the etchant may be combined with etch impurities occurring from the first to third interlayer insulating patterns 105a, 150b, and 140 to form an etch by-product BYP. The etch by-product BYP may cover the top surfaces of the first to third interlayer insulating patterns 105a, 105b and 140, and the sidewalls of the inner spaces IS. The etch by-product BYP may close upper portions of the inner spaces IS. The etch by-product BYP may be a porous layer including pores P. The etchant may permeate into the pores P. By the etchant provided in the pores P, the upper portions of the inner spaces IS may be etched more than lower portions of the inner spaces IS. Thus, upper widths WD1 of the inner spaces IS may be greater than lower widths WD2 of the inner spaces IS (FIG. 13), and the upper portion of each of the inner spaces IS may have a width which becomes greater toward its top end. Sidewalls of the upper portions of the inner spaces IS may be rounded.

The etching process may be performed by, e.g., a dry cleaning process, a dry etching process, or a wet etching process. For example, the dry cleaning process may be a chemical oxide removal (COR) process or a pulsed dry cleaning (PDC) process. For example, the dry etching process may be an ion beam etch (IBE) process, a CF₄ treatment process, or a chemical oxide removal (COR) process. For example, the wet etching process may use an etching solution, e.g., O₃HF, HF, or SC1. After expanding the widths of the upper portions of the inner spaces IS, the etch by-product BYP may be removed. The etch by-product BYP may be evaporated by a thermal treatment process. The thermal treatment process may be performed at about 70 degrees Celsius or more. The top surfaces of the first to third interlayer insulating patterns 105a, 105b and 140, and the sidewalls of the inner spaces IS may be exposed by the removal of the etch by-product BYP.

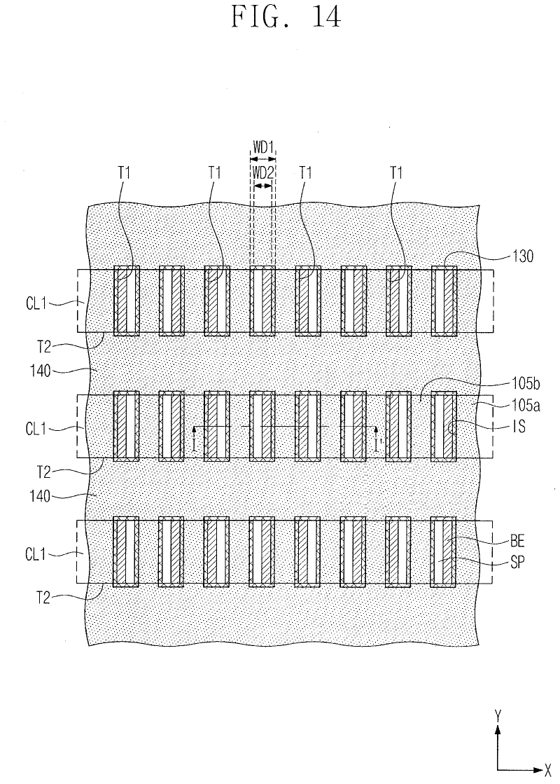

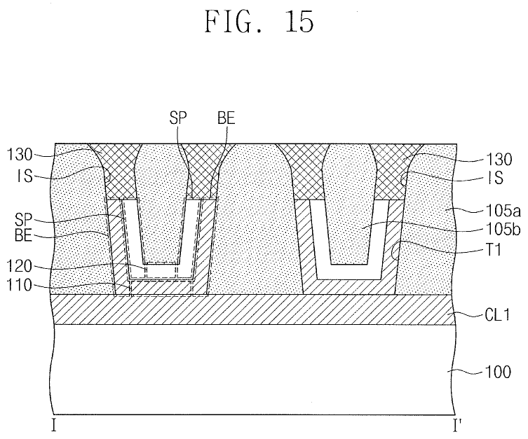

Referring to FIGS. 14 and 15, the phase change patterns 130 may be formed in the inner spaces IS, respectively. In some embodiments, a phase change layer may be formed to fill the inner spaces IS and to cover the top surfaces of the first to third interlayer insulating patterns 105a, 105b and 140, and then, a planarization process may be performed on the phase change layer until the top surfaces of the first to third interlayer insulating patterns 105a, 105b and 140 are exposed, thereby forming the phase change patterns 130. For example, the phase change patterns 130 may be formed of a compound that includes at least one of Te or Se (i.e., chalcogenide elements) and at least one of Ge, Sb, Bi, Pb, Sn, Ag, As, S, Si, In, Ti, Ga, P, O, or C. For example, the phase change patterns 130 may include at least one of GeSbTe, GeTeAs, SbTeSe, GeTe, SbTe, SeTeSn, GeTeSe, SbSeBi, GeBiTe, GeTeTi, InSe, GaTeSe, or InSbTe.

In other embodiments, the phase change patterns 130 may include at least one of a perovskite compound or a conductive metal oxide. For example, the phase change patterns 130 may include at least one of niobium oxide, titanium oxide, nickel oxide, zirconium oxide, vanadium oxide, (Pr,Ca)MnO₃ (PCMO), strontium-titanium oxide, barium-strontium-titanium oxide, strontium-zirconium oxide. barium-zirconium oxide, or barium-strontium-zirconium oxide. When the phase change patterns 130 include a transition metal oxide, a dielectric constant of the phase change patterns 130 may be greater than a dielectric constant of silicon oxide. In still other embodiments, the phase change patterns 130 may have a double-layer structure of a conductive metal oxide layer and a tunnel insulating layer or may have a triple-layer structure of a first conductive metal oxide layer, a tunnel insulating layer and a second conductive metal oxide layer. The tunnel insulating layer may include aluminum oxide, hafnium oxide, or silicon oxide.

According to the embodiments, the etching process may be performed to expand or enlarge the widths of the upper portions of the inner spaces IS, and thus the phase change patterns 130 may fill the inner spaces IS without a void. As a result, reliability of the variable resistance memory device may be improved.

Referring again to FIGS. 1 and 2, the intermediate electrodes ME may be formed on top surfaces of the phase change patterns 130, respectively. In some embodiments, upper portions of the phase change patterns 130 may be etched to recess top surfaces of the phase change patterns 130 from the top surfaces of the first to third interlayer insulating patterns 105a, 105b and 140, and a metal layer may be formed on the top surfaces of the first to third interlayer insulating patterns 105a, 105b and 140 and in the inner spaces IS re-formed on the recessed top surfaces of the phase change patterns 130. Thereafter, a planarization process may be performed on the metal layer until the top surfaces of the first to third interlayer insulating patterns 105a, 105b, and 140 are exposed, thereby forming the intermediate electrodes ME. The intermediate electrodes ME may be formed locally in the inner spaces IS. For example, the intermediate electrodes ME may include at least one of W, Ti, Al, Cu, C, CN, TiN, TiAlN, TiSiN, TiCN, WN, CoSiN, WSiN, TaN, TaCN, TaSiN, or TiO.

In certain embodiments, a conductive layer may be formed to cover the top surfaces of the phase change patterns 130 and the top surfaces of the first to third interlayer insulating patterns 105a, 105b and 140, and the conductive layer may be patterned to form the intermediate electrodes ME. In this case, the intermediate electrodes ME may not be formed in the inner spaces IS, as illustrated in FIG. 4.

The switching pattern 150 and the top electrode UE may be sequentially formed on the top surface of each of the intermediate electrodes ME. In some embodiments, a switching layer and a metal layer may be sequentially formed on the top surfaces of the first to third interlayer insulating patterns 105a, 105b and 140, and then, the metal layer and the switching layer may be patterned to form the switching patterns 150 and the top electrodes UE. Each of the switching patterns 150 may be a diode or may be an element based on a threshold switching phenomenon having a nonlinear I-V curve (e.g., a S-shaped I-V curve).

For example, each of the switching patterns 150 may be an ovonic threshold switch (OTS) element having a bi-directional characteristic. In some embodiments, the switching pattern 150 may be the diode. In this case, the switching pattern 150 may include a first junction pattern and a second junction pattern. The first junction pattern may have a first conductivity type, and the second junction pattern may have a second conductivity type different from the first conductivity type. For example, the first conductivity type may be an N type, and the second conductivity type may be a P type. For example, the second junction pattern may include dopants of the second conductivity type. The first junction pattern may include dopants of the first conductivity type and dopants of the second conductivity type. In this case, a concentration of the first conductivity type dopants may be higher than a concentration of the second conductivity type dopants, in the first junction pattern. In some embodiments, the switching pattern 150 may be a silicon diode or oxide diode which has a rectifying property. For example, the switching pattern 150 may be a silicon diode of P-type silicon and N-type silicon or may be an oxide diode of P-type NiOₓ and N-type TiOₓ or an oxide diode of P-type CuOₓ and N-type TiOₓ. For example, the top electrodes UE may include at least one of W, Ti, Al, Cu, C, CN, TiN, TiAlN, TiSiN, TiCN, WN, CoSiN, WSiN, TaN, TaCN, TaSiN, or TiO.

The fourth interlayer insulating layer 160 may be formed on the first to third interlayer insulating patterns 105a, 105b, and 140. The fourth interlayer insulating layer 160 may cover the top surfaces of the first to third interlayer insulating patterns 105a, 105b and 140, sidewalls of the switching patterns 150, and sidewalls of the top electrodes UE. For example, the fourth interlayer insulating layer 160 may include a silicon nitride layer. Second conductive lines CL2 may be formed on top surfaces of the top electrodes UE. Each of the second conductive lines CL2 may extend in the second direction Y along the top electrodes UE arranged in the second direction Y. Each of the second conductive lines CL2 may be connected to the top electrodes UE arranged in the second direction Y. For example, the second conductive lines CL2 may include at least one of a metal material (e.g., copper or aluminum) or a conductive metal nitride (e.g., TiN or WN).

By way of summation and review, embodiments provide a variable resistance memory device with improved reliability. That is, according to the embodiments, an etching process may be performed to expand or enlarge the widths of the upper portions of the inner spaces surrounded by the interlayer insulating patterns, e.g., so the inner spaces with high aspect ratios may have wide tops and curved corners at the tops. As such, the filling ability of the deposited material may be improved within the inner spaces, so the phase change patterns may fill the inner spaces without a void. As a result, the reliability of the variable resistance memory device may be improved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A variable resistance memory device, comprising:
an interlayer insulating structure on a substrate, the interlayer insulating structure having a hole;
a bottom electrode in a lower portion of the hole; and
a pattern in an upper portion of the hole, the pattern including at least one of a phase change pattern or an intermediate electrode, a sidewall of the pattern defining an angle with a top surface of the substrate, and the angle decreasing as a vertical distance from the substrate increases.

2. The variable resistance memory device as claimed in claim 1, wherein the pattern includes:
the phase change pattern on a top surface of the bottom electrode; and
the intermediate electrode on a top surface of the phase change pattern.

3. The variable resistance memory device as claimed in claim 2, wherein a top surface of the intermediate electrode is substantially coplanar with a top surface of the interlayer insulating structure.

4. The variable resistance memory device as claimed in claim 2, wherein the phase change pattern includes:
a first portion between the substrate and the intermediate electrode, a sidewall of the first portion defining a first angle with the top surface of the substrate; and
a second portion between the first portion and the intermediate electrode, a sidewall of the second portion defining a second angle with the top surface of the substrate, and the first angle being greater than the second angle,
wherein a sidewall of the intermediate electrode defines a third angle with the top surface of the substrate, the second angle being greater than the third angle.

5. (canceled)

6. The variable resistance memory device as claimed in claim 1, wherein the pattern is the phase change pattern, a top surface of the phase change pattern being substantially coplanar with a top surface of the interlayer insulating structure, and the intermediate electrode being on the top surface of the phase change pattern.

7. The variable resistance memory device as claimed in claim 6, wherein:
a sidewall of the phase change pattern defines the angle with the top surface of the substrate,
a sidewall of the intermediate electrode defines a second angle with the top surface of the substrate, the angle being different from the second angle, and the second angle being a substantially right angle.

8. The variable resistance memory device as claimed in claim 6, wherein the phase change pattern includes:
a first portion between the bottom electrode and the intermediate electrode; and
a second portion between the first portion and the intermediate electrode,
wherein a width of the first portion is substantially uniform, and
wherein a width of the second portion becomes greater from the first portion toward the intermediate electrode.

9. The variable resistance memory device as claimed in claim 1, wherein the pattern is the intermediate electrode, and the phase change pattern is between the bottom electrode and the intermediate electrode in the lower portion of the hole.

10. The variable resistance memory device as claimed in claim 9, wherein a second angle of a sidewall of the phase change pattern with the top surface of the substrate is greater than the angle of the intermediate electrode.

11. A variable resistance memory device, comprising:
an interlayer insulating structure on a substrate, the interlayer insulating structure having a hole;
a bottom electrode in a lower portion of the hole; and
a pattern in an upper portion of the hole, the pattern including at least one of a phase change pattern or an intermediate electrode, and a sidewall of the pattern being concave.

12. The variable resistance memory device as claimed in claim 11, wherein the pattern includes:
the phase change pattern on a top surface of the bottom electrode; and
the intermediate electrode on a top surface of the phase change pattern.

13. The variable resistance memory device as claimed in claim 12, wherein a bottom surface of the phase change pattern has a first width, and the top surface of the phase change pattern has a second width, the first width being less than the second width.

14. The variable resistance memory device as claimed in claim 12, further comprising:
a spacer in the lower portion of the hole,
wherein the bottom electrode is on a first sidewall of the hole, and
wherein the spacer is on a second sidewall of the hole, which is opposite to the first sidewall.

15. The variable resistance memory device as claimed in claim 14, wherein a sum of a width of the bottom electrode and a width of the spacer is less than a width of a top surface of the intermediate electrode.

16. The variable resistance memory device as claimed in claim 12, wherein a width of a bottom surface of the intermediate electrode is less than a width of a top surface of the intermediate electrode.

17. The variable resistance memory device as claimed in claim 12, wherein:
a sidewall of the phase change pattern defines a first angle with a top surface of the substrate,
a sidewall of the intermediate electrode forms a second angle with the top surface of the substrate, and
the first angle is greater than the second angle.

18. (canceled)

19. (canceled)

20. A variable resistance memory device, comprising:
an interlayer insulating structure on a substrate, the interlayer insulating structure having a hole;
a bottom electrode in a lower portion of the hole; and
a phase change pattern in an upper portion of the hole, a first gradient of a sidewall of the lower portion of the hole being greater than a second gradient of a sidewall of the upper portion of the hole.

21. The variable resistance memory device as claimed in claim 20, wherein the second gradient decreases as a vertical distance from the substrate increases.

22. The variable resistance memory device as claimed in claim 20, further comprising an intermediate electrode on a top surface of the phase change pattern in the upper portion of the hole, the phase change pattern and the intermediate electrode being in contact with the sidewall of the upper portion of the hole.

23. The variable resistance memory device as claimed in claim 20, further comprising an intermediate electrode on a top surface of the phase change pattern, the intermediate electrode being spaced apart from the sidewall of the upper portion of the hole.

24. (canceled)

25. (canceled)
